(19) United States
(12) Patent Application Publication
(10) Pub. No.: US 2007/0145511 A1
(43) Pub. Date: Jun. 28, 2007

(54) CMOS Image Sensor

(76) Inventor: Keun Hyuk Lim, Seoul (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/615,148

(22) Filed: Dec. 22, 2006

(30) Foreign Application Priority Data
Dec. 28, 2005 (KR) 10-2005-0132485

(51) Int. Cl. H01L 31/06

(52) U.S. Cl. 257/462

(57) ABSTRACT

A CMOS image sensor is provided. The CMOS image sensor includes: a semiconductor substrate having a photodiode region and a floating diffusion region defined thereon; a gate electrode formed inside the photodiode region of the semiconductor substrate; a low concentration impurity region formed on the photodiode region at one side of the gate electrode; and a high concentration impurity region formed at the other side of the gate electrode, including on the floating diffusion region.

### RELATED APPLICATION(S)

This application claims priority under 35 U.S.C. §119(e) of Korean Patent Application No. 10-2005-0132485 filed Dec. 28, 2005, which is incorporated herein by reference in its entirety.

### FIELD OF THE INVENTION

The present invention relates to a CMOS image sensor.

### BACKGROUND OF THE INVENTION

In general, an image sensor is a semiconductor device that converts an optical image into an electric signal, and is mainly classified as a charge coupled device (CCD) and a complementary metal oxide semiconductor (CMOS) image sensor.

The CCD includes a plurality of photodiodes (PDs), a plurality of vertical charge coupled devices (VCCDs), a plurality of horizontal charge coupled devices (HCCDs), and a sense amplifier. The PDs are arranged in a matrix to convert light signals into electric signals. The VCCDs are formed between PDs arranged in the matrix and in a vertical direction, and transmit charge generated from each of the PDs in a vertical direction. The HCCDs transmit the charge transmitted from the VCCDs in a horizontal direction. The sense amplifier senses the charge transmitted in the horizontal to output electric signals.

However, since a method of driving the CCD is complex, consumes a lot of power, and requires a high number of photolithography processes, the manufacturing process is complicated.

Moreover, it is difficult to integrate a control circuit, a signal processing circuit, and an A/D converter into a single CCD chip and, thus, reduce the size of a product.

Recently, to overcome disadvantages of the CCD, the CMOS image sensor has come under scrutiny as a next generation image sensor. The CMOS image sensor takes advantage of a CMOS technology using a peripheral circuit such as a control circuit and a signal processing circuit, and forms MOS transistors corresponding to a number of pixels on a semiconductor substrate. The CMOS image sensor is a device that employs a switching method that sequentially detects an output of each unit pixel by using the MOS transistors.

That is, the CMOS image sensor includes the MOS transistor in the unit pixel and sequentially detects an electric signal of each of the unit pixel to display an image through the switching method.

The CMOS image sensor utilizes a CMOS manufacturing technology, and thus has advantages of low power consumption and a simple manufacturing process because of the fewer number of photolithography steps as compared with the CCD.

Moreover, since a control circuit, a signal processing circuit, and an A/D converter can be integrated into a single CMOS chip, the size of a product can be reduced.

Accordingly, the CMOS image sensor is widely used in various applications such as a digital still camera and a digital video camera.

The CMOS image sensor is generally classified as a 3T type, 4T type, or a 5T type according to the number of transistors formed in a unit pixel. For example, the 3T type CMOS image sensor includes one PD and three transistors, and the 4T type includes one PD and four transistors.

FIG. 1 is an equivalent circuit diagram of a related art 4T type CMOS image sensor. FIG. 2 is a layout of a unit pixel of a related art 4T type CMOS image sensor.

As illustrated in FIG. 1, the unit pixel 100 of the CMOS image sensor includes a photodiode 110 and four transistors.

Here, the four transistors are a transfer transistor 120, a reset transistor 130, a drive transistor 140, and a select transistor 150.

In addition, a load transistor 160 is electrically connected to an output (Out) of the unit pixel 100.

Here, FD, Tx, Rx, Dx, and Sx represent a floating diffusion region, a gate voltage of a select transistor 120, a gate voltage of a reset transistor 130, a gate voltage of a drive transistor 140, and a gate voltage of a select transistor 150, respectively.

In a unit pixel of a related art 4T type CMOS image sensor, a device isolation layer is formed on a region except for a defined active region (a solid line) as illustrated in FIG. 2.

One PD 110 is formed on a wide region of the active region, and gate electrodes of four transistors are formed overlapping the remaining region of the active region.

That is, a transfer transistor 120 is formed by the gate electrode 23. A reset transistor 130 is formed by the gate electrode 33. A drive transistor 140 is formed by the gate electrode 43. A select transistor 150 is formed by the gate electrode 53.

An impurity ion is implanted in the active region of each transistor to form a source/drain region S/D of each transistor.

A sectional view of a PD and a transfer transistor of a related art CMOS image sensor having the above structure will be described with reference to FIGS. 2 and 3.

FIG. 3 is a sectional view taken along line I-I′ of FIG. 2.

As illustrated in FIG. 3, a gate electrode 23 of the transfer transistor is formed on a semiconductor substrate with a gate insulation layer 22 interposed therebetween. The semiconductor substrate 21 has a photodiode region and a floating diffusion region FD defined thereon.

Here, the gate electrode 23 is formed on the photodiode region.

A low concentration n⁻ diffusion region 24 is formed on the photodiode region PD at one side of the gate electrode 23. A high concentration n⁺ diffusion region 25 is formed on a floating diffusion region FD at the other side of the gate electrode 23.

Referring to FIG. 2, an electron \textcircled{e} generated when light is incident into the photodiode region PD is stored on the floating diffusion region FD through a channel region below the gate electrode 23 by turning on the gate electrode 23 of the transfer transistor.

Next, the electron stored on the floating diffusion region FD serves as the gate voltage of the drive transistor 140.

However, the related art CMOS image sensor has disadvantages as follows.

That is, since the gate electrode of the transfer transistor is formed extending on an end portion of the photodiode region, electrons disappear due to recombination during electron movement. Moreover, since the size of the floating diffusion region FD is small, charge saturation easily occurs. Therefore, an amount of light for reaction is limited.

### BRIEF SUMMARY

Accordingly, embodiments of the present invention are directed to a CMOS image sensor that substantially obviates one or more problems due to limitations and disadvantages of the related art.

An object of embodiments of the present invention is to provide a CMOS image sensor capable of smoothly flowing electrons delivered into a floating diffusion region by forming a gate electrode of a transfer transistor inside a photodiode region, and simultaneously increasing a capacity of a floating diffusion region by enlarging the size of the floating diffusion region.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, there is provided a CMOS image sensor including: a semiconductor substrate having a photodiode region and a floating diffusion region defined thereon; a gate electrode formed on the photodiode region of the semiconductor substrate with a gate insulating layer interposed therebetween; a low concentration impurity region formed on the photodiode region at one side of the gate electrode; and a high concentration impurity region formed on the floating region at the other side of the gate electrode.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. I

FIG. 1 is an equivalent circuit diagram of a related art 4T CMOS image sensor.

FIG. 2 is a layout of a unit pixel of a related art 4T CMOS image sensor.

FIG. 3 is a sectional view taken along line I-I′ of FIG. 2.

FIG. 4 is a layout of a CMOS image according to an embodiment of the present invention.

FIG. 5 is a sectional view of a CMOS image sensor taken along line IV-IV′ of FIG. 4.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

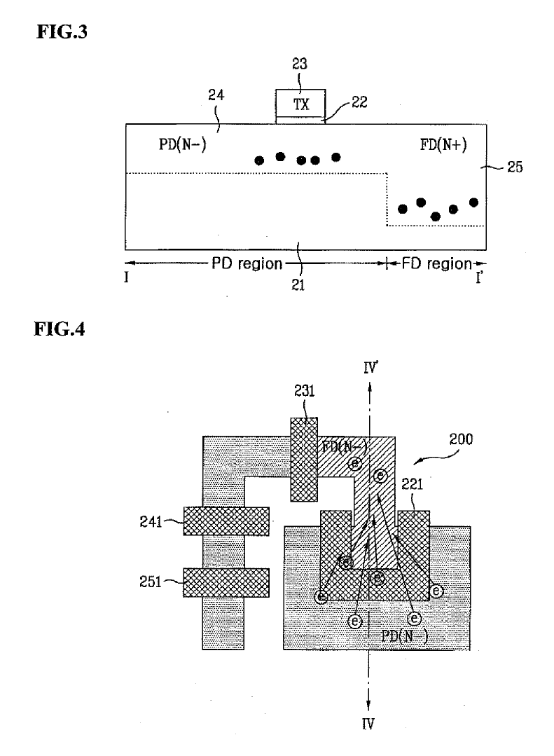

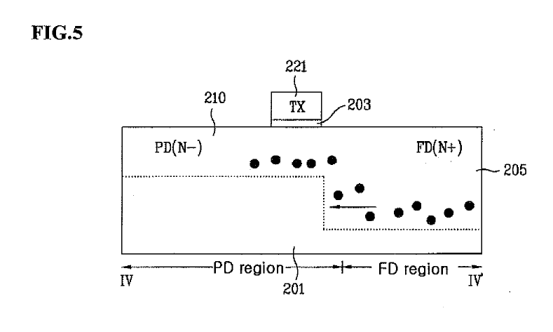

FIG. 4 is a layout of a complementary metal oxide semiconductor (CMOS) image according to an embodiment of the present invention.

As illustrated in FIG. 4, a unit pixel 200 of the CMOS image sensor is a light to electricity converter and includes a photodiode PD and four transistors.

Here, the four transistors are a transfer transistor, a reset transistor, a drive transistor, and a select transistor.

The unit pixel 200 of a 4T type CMOS image sensor includes an isolation region formed on a region of the substrate and defines the active region.

A photodiode PD is formed on a wide region of the active region, and the floating diffusion region FD is formed on the active region adjacent to a photodiode region PD. Gate electrodes 221, 231, 241, and 251 of four transistors are formed overlapping the active region.

That is, a transfer transistor is formed by the gate electrode 221, and a reset transistor is formed by the gate electrode 231. A drive transistor is formed by the gate electrode 241, and a select transistor is formed by the gate electrode 251.

Here, an impurity ion can be implanted in the active region of each transistor to form a source/drain region S/D of each transistor.

In a preferred embodiment, the gate electrode 221 of the transfer transistor is formed in a horseshoe or ‘C’ shape.

Referring to FIG. 5, the active region of a semiconductor substrate 201 can include a PD region and a FD region. A device isolation layer (not shown) can be formed in the substrate 201 to define the active region.

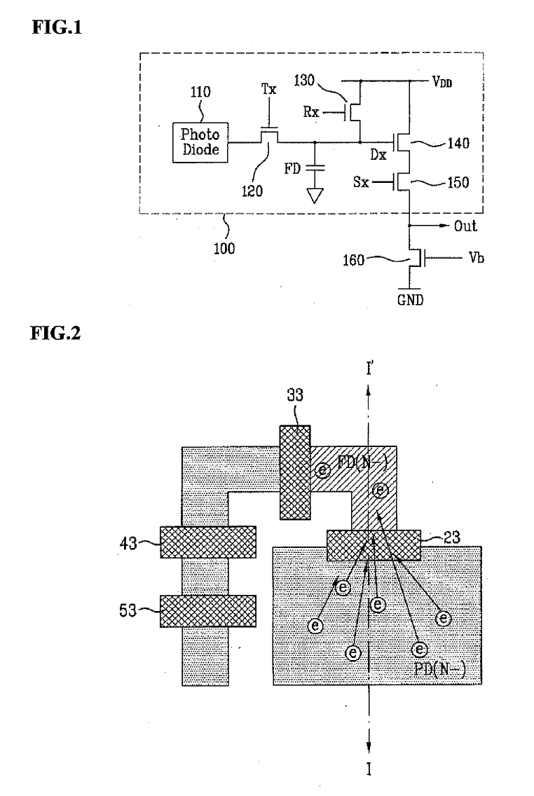

A gate insulating layer 203 and a gate electrode 221 can be formed on a semiconductor substrate 201 cutting into the photodiode region PD. The gate electrode 221 can have a “C” shape such as shown in FIG. 2. An n⁻ diffusion region 210 for the photodiode region PD can be formed at one side of the gate electrode 221.

In addition, an n⁺ diffusion region 205 can be formed on the active region at the other side of the gate electrode 221, i.e., the floating diffusion region FD.

Here, the n+ diffusion region 205 can be formed extending into the curved cut of the gate electrode 221.

That is, the gate electrode 221 surrounds one end of the floating diffusion region FD.

Additionally, an interlayer insulation layer (not shown) can be formed on an entire surface of the semiconductor substrate 201 having the gate electrode 221. In one embodiment a metal line (not shown) can be formed to connect the floating diffusion region 205 and a source/drain region of the drive transistor by penetrating the interlayer insulation layer.

Accordingly, an electron \textcircled{e} generated when light is incident into the photodiode PD is stored on the floating diffusion region FD through a channel region below the gate electrode 221 by turning on the gate electrode 221 of the transfer transistor.

Next, the electron stored on the floating diffusion region FD serves as a gate voltage of the drive transistor 140 (shown in FIG. 1).

Accordingly, embodiments of the present invention provide CMOS image sensors capable of reducing electron loss by forming the gate electrode 221 of the transfer transistor inside the photodiode region PD to reduce a movement path of an electron and simultaneously expanding an operational range of the image sensor by increasing capacity of a floating diffusion region.

The CMOS image of embodiments of the present invention has advantages as follows.

First, since the gate electrode of the transfer transistor is formed inside the photodiode region, which reduces a movement path of the electron, the loss of electrons can be reduced.

Second, since the capacity of the floating diffusion region is increased to pass more electrons, the operational range of the image sensor can be increased.

Third, the sensitivity and characteristics of an image sensor can be improved by reducing the loss of the electrons and expanding an operation range of the image sensor.

It will be apparent to those skilled in the art that various modifications and variations can be made in the present invention. Thus, it is intended that the present invention covers the modifications and variations of this invention provided they come within the scope of the appended claims and their equivalents.

I claim:

1. A complementary metal oxide semiconductor (CMOS) image sensor, comprising:
a gate electrode formed inside a photodiode region of a semiconductor substrate with a gate insulating layer interposed therebetween;
a low concentration impurity region formed on the photodiode region at one side of the gate electrode; and
a high concentration impurity region formed on an active region of the semiconductor substrate at a second side of the gate electrode, including on a floating diffusion region

2. The CMOS image sensor according to claim 1, wherein the gate electrode is formed around at least portions of three sides of the floating diffusion region.

3. The CMOS image sensor according to claim 1, wherein the high concentration impurity region is formed extending to a region within a convex shaped portion of the gate electrode.

4. The CMOS image sensor according to claim 1, wherein the gate electrode is a gate electrode of a transfer transistor.

5. The CMOS image sensor according to claim 1, wherein the gate electrode borders a portion of one end of the floating diffusion region.

6. The CMOS image sensor according to claim 1, wherein the gate electrode is formed cutting into the photodiode region such that the photodiode region remains on three sides of the gate electrode.
